(19) United States
(12) Patent Application Publication
(10) Pub. No.: US 2026/0250527 A1
(43) Pub. Date: Aug. 27, 2026

(54) CONDUCTIVE INK COMPOSITION AND WIRING PATTERN

(71) Applicant: DUPONT ELECTRONICS, INC., Wilmington, DE (US)

(72) Inventors: CHING MAO HUANG, HSINCHU CITY (TW); YEN MING TSENG, HSINCHU CITY (TW); TSUNG HAN TSAI, HSINCHU CITY (TW); LI YEN LIN, HSINCHU CITY (TW)

(21) Appl. No.: 19/537,715

(22) Filed: Feb. 12, 2026

Related U.S. Application Data
(60) Provisional application No. 63/762,484, filed on Feb. 24, 2025.

(51) Int. Cl. C09D 11/037; C09D 11/322

(52) U.S. Cl. CPC C09D 11/037; C09D 11/322

(57) ABSTRACT

The present disclosure provides a conductive ink composition for forming a wiring pattern by a one-step IR laser irradiation process. The conductive ink composition comprises: silver nanoparticles, a binder and a solvent, and the one-step IR laser irradiation process is performed with a wavelength ranging from 800 nm to 1150 nm and a pulse duration of 100 femtoseconds to 1000 femtoseconds. The present disclosure also provides a wiring pattern manufactured from the conductive ink composition by the one-step IR laser irradiation process.

### FIELD OF THE INVENTION

The present disclosure provides a conductive ink composition for forming a wiring pattern by a one-step IR laser irradiation process, and a wiring pattern manufactured therefrom. The conductive ink composition and wiring pattern can be applied in various fields such as printed circuit broads, displays, and advanced packaging.

### BACKGROUND OF THE INVENTION

Conventionally, a wiring pattern of an electronic circuit can be formed by photolithography, where unwanted portions of a metal layer are etched away to provide a desired pattern. However, photolithography typically involves high energy and water consumption, numerous production steps and a considerable amount of wasted materials.

As an alternative to photolithography, printing technology (such as pressure-controlled direct printing and electrohydrodynamic (EHD) printing) has been studied and developed. In contrast to photolithography, this technology is an additive process rather than a subtractive process and has the advantage of producing less wasted materials. Generally, printing technology involves extrusion of an ink composition comprising solvent and metal particles though a nozzle onto a surface of a substrate, drying the printed ink composition to remove solvent and sintering the metal particles in the printed ink composition to form continuous metal lines constituting a wiring pattern.

Traditionally, the drying and sintering processes are performed thermally, where the printed ink composition is under thermal heating alone with the substrate carrying it at a high temperature (such as 150° C.-350° C.) to sinter metal particles. Applications of such thermal sintering processes are restricted by the thermal stability of the ink composition and substrate, especially with materials having a lower glass transition temperature and/or decomposition temperature such as flexible polymers or paper.

In view of the shortcomings of thermal sintering, photonic sintering has been developed to perform sintering locally and at a comparably lower temperature. However, components of an ink composition may be relatively active or relatively inactive (compared with one another) under the same predefined wavelength so that they may need to be handled at different wavelengths. For example, a certain solvent can be rapidly removed at a certain wavelength but the metal particles used with it can barely be sintered at the same wavelength, or certain metal particles may be well fused at a certain wavelength but the solvent used cannot be sufficiently removed at the same wavelength. In these cases, the drying and sintering processes would need multi-stage light irradiation or would not be possible at all. The selection of components of ink compositions and suitable irradiation wavelengths, while simplifying production steps and reducing energy consumption, remains an urgent issue that needs to be addressed.

### SUMMARY OF THE INVENTION

In view of the aforementioned technical problems, the present disclosure provides a conductive ink composition that can be dried and sintered in a single irradiation step with a monochromatic light to form a targeted pattern.

Accordingly, an objective of the present disclosure is to provide a conductive ink composition for forming a wiring pattern by a one-step IR laser irradiation process, wherein based on a total weight of the conductive ink composition, the conductive ink composition comprises:
(A) 20 wt % to 95 wt % of silver nanoparticles;
(B) 0.1 wt % to 20 wt % of a binder; and
(C) 4.9 wt % to 79.9 wt % of a solvent;
wherein based on a total weight of the binder (B) and silver nanoparticles (A), the amount of the binder (B) is 4 wt % to 45 wt %; and
wherein the one-step IR laser irradiation process is performed with a wavelength ranging from 800 nm to 1150 nm and a pulse duration of 100 femtoseconds to 1000 femtoseconds.

In an embodiment of the present disclosure, the conductive ink composition has a viscosity of 2,000 to 12,000 cPs measured at 25° C. and a shear rate of 85 s⁻¹.

In an embodiment of the present disclosure, the silver nanoparticles (A) have an average diameter of 20 nm to 400 nm.

In an embodiment of the present disclosure, the binder (B) is selected from the group consisting of poly(vinyl acetate), poly(vinyl alcohol) (PVA), polydioxanone (PDO), polyacrylamide (PAM), poly(glycolic acid) (PGA), poly-(ε-caprolactone) (PCL), poly(L-lactic acid) (PLLA), polyurethane (PU), polyacrylate, polyvinylpyrrolidone (PVP), poly(vinyl alcohol-co-ethylene), polyethylene glycol (PEG), poly(tetramethylene ether) glycol (PTMEG), ethyl cellulose (EC), cellulose acetate, hydroxypropylmethyl cellulose (HPMC), polyvinyl butyral (PVB), and combinations thereof.

In an embodiment of the present disclosure, the solvent (C) has a boiling point ranging from 160° C. to 270° C.

In an embodiment of the present disclosure, the solvent (C) is alkoxy alcohol, alkoxy ester, or alicyclic alcohol.

In an embodiment of the present disclosure, the solvent (C) is selected from the group consisting of ethylene glycol monobutyl ether, ethylene glycol monoisobutyl ether, ethylene glycol monohexyl ether, ethylene glycol mono-2-ethylhexyl ether, diethylene glycol monomethyl ether, diethylene glycol monoethyl ether, diethylene glycol monopropyl ether, diethylene glycol monobutyl ether (also referred to as butyl carbitol), diethylene glycol monoisobutyl ether, diethylene glycol monohexyl ether, triethylene glycol monomethyl ether, triethylene glycol monoethyl ether, triethylene glycol monopropyl ether, ethylene glycol monoethyl ether acetate, diethylene glycol monoethyl ether acetate (also referred to as carbitol acetate), diethylene glycol monobutyl ether acetate (also referred to as butyl carbitol acetate), and terpineol.

In an embodiment of the present disclosure, the solvent (C) is void of polyol (—OH group>2) or water.

Another objective of the present disclosure is to provide a wiring pattern, which is manufactured from the aforementioned conductive ink composition by the one-step IR laser irradiation process.

In an embodiment of the present disclosure, the wiring pattern is formed on a substrate selected from the group consisting of Cu, Ag, Ti, Ti—Al—Ti stack, glass, Al₂O₃, BaTiO₃, AlN, TiO₂, ZrO₂, polyimide (PI), polyethylene terephthalate (PET), polyethylene naphthalate (PEN), polyethylene furandicarboxylate (PEF), polycarbonate (PC), poly(methyl methacrylate) (PMMA), cyclic olefin polymer (COP), fiber-reinforced composite, and combinations thereof.

To render the above objectives, technical features, and advantages of the present disclosure more apparent, the present disclosure will be described in detail with reference to some embodiments hereinafter.

### DETAILED DESCRIPTION OF THE INVENTION

Hereinafter, some embodiments of the present disclosure will be described in detail. However, the present disclosure may be embodied in various embodiments, and the protection scope of the present disclosure should not be limited to those described in the specification.

As used herein, the expressions “a”, “the”, or the like recited in the specification and in the claims should include both the singular and the plural forms unless stated otherwise.

The conductive ink composition and wiring pattern of the present disclosure are described in detail below.

### Conductive Ink Composition

In the present disclosure, the conductive ink composition comprises (A) silver nanoparticles, (B) a binder and (C) a solvent as essential components and may further comprise optional components. The components are described in detail below.

The conductive ink composition of the present disclosure comprises silver nanoparticles to impart conductivity to products made from the conductive ink composition. Among electrically conductive substances, silver is highly regarded because it has high electrical and thermal conductivity, and is relatively less expensive compared to gold nanoparticles or graphene. Additionally, silver nanoparticles have a drastically lower melting point compared to bulk silver, which may be advantageous for application to flexible substrates such as polymers and papers.

The size of the silver nanoparticles can be selected depending on the production process. For example, to facilitate sintering, the size of the silver nanoparticles can be selected for optimal absorption of the light/heat source. In an embodiment of the present disclosure, the silver nanoparticles may have an average diameter of 20 nm to 400 nm, or 50 nm to 350 nm, or 100 nm to 160 nm. For example, the average diameter of the silver nanoparticles can be 20 nm, 30 nm, 40 nm, 50 nm, 60 nm, 70 nm, 80 nm, 90 nm, 100 nm, 110 nm, 120 nm, 130 nm, 140 nm, 150 nm, 160 nm, 170 nm, 180 nm, 190 nm, 200 nm, 220 nm, 240, nm, 250 nm, 260 nm, 280 nm 300 nm, 320 nm, 340 nm, 350 nm, 360 nm, 380 nm, or 400 nm, or within a range between any two of the values described herein. The average diameter of the silver nanoparticles can be measured by using a dynamic light scattering particle size analyzer.

The amount of the silver nanoparticles can range from 20 wt % to 95 wt %, or 20 wt % to 75 wt %, or 25 wt % to 70 wt %, based on a total weight of the conductive ink composition. For example, based on the total weight of the conductive ink composition, the amount of the silver nanoparticles can be 20 wt %, 22.5 wt %, 25 wt %, 27.5 wt %, 30 wt %, 32.5 wt %, 35 wt %, 37.5 wt %, 40 wt %, 42.5 wt %, 45 wt %, 47.5 wt %, 50 wt %, 52.5 wt %, 55 wt %, 57.5 wt %, 60 wt %, 62.5 wt %, 65 wt %, 67.5 wt %, 70 wt %, 72.5 wt %, 75 wt %, 77.5 wt %, 80 wt %, 82.5 wt %, 85 wt %, 87.5 wt %, 90 wt %, 92.5 wt %, or 95 wt %, or within a range between any two of the values described herein. If the amount of the silver nanoparticles is higher than the range above, silver nanoparticles may aggregate and not well-dispersed. It may affect the operability.

The silver nanoparticles can be prepared by methods known in the art or obtained commercially. In some cases, the silver nanoparticles are obtained commercially in the form of a silver nanoparticle slurry. If desired, the silver nanoparticles may be subjected to surface treatment or modification before use.

In the present disclosure, the conductive ink composition comprises a binder. The binder may play a role in imparting good adhesion to substrate when the conductive ink composition is ejected onto a substrate during printing process. The binder may also facilitate the dispersion of the silver nanoparticles and prevent them from agglomeration.

The type of the binder can be selected such that the binder has good affinity with the silver nanoparticles. The type of the binder can also be selected such that the binder is partially evaporated or decomposed under the predetermined light/heat source to facilitate the sintering of the silver nanoparticles.

In an embodiment of the present disclosure, the binder can be selected from the group consisting of poly(vinyl acetate), poly(vinyl alcohol) (PVA), polydioxanone (PDO), polyacrylamide (PAM), poly(glycolic acid) (PGA), poly-(ε-caprolactone) (PCL), poly(L-lactic acid) (PLLA), polyurethane (PU), polyacrylate, polyvinylpyrrolidone (PVP), poly(vinyl alcohol-co-ethylene), polyethylene glycol (PEG), poly(tetramethylene ether) glycol (PTMEG), ethyl cellulose (EC), cellulose acetate, hydroxypropylmethyl cellulose (HPMC), polyvinyl butyral (PVB), and combinations thereof. In a more specific embodiment, the binder is selected from the group consisting of polyurethane (PU), polyacrylate, polyvinylpyrrolidone (PVP), ethyl cellulose (EC), cellulose acetate, hydroxypropylmethyl cellulose (HPMC), and combinations thereof.

The amount of the binder can range from 0.1 wt % to 20 wt %, or 2.5 wt % to 18 wt %, or 3 wt % to 15 wt %, based on a total weight of the conductive ink composition. For example, based on the total weight of the conductive ink composition, the amount of the binder can be 0.1 wt %, 0.5 wt %, 1 wt %, 2 wt %, 2.5 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, or 20 wt %, or within a range between any two of the values described herein.

Further, the amount of the binder based on a total weight of the binder and silver nanoparticles can range from 4 wt % to 45 wt %, or 4.5 wt % to 40 wt %, or 5 wt % to 35 wt %. For example, based on the total weight of the binder and silver nanoparticles, the amount of the binder can be 4 wt %, 4.5 wt %, 5 wt %, 5.5 wt %, 6 wt %, 7.5 wt %, 10 wt %, 12.5 wt %, 15 wt %, 17.5 wt %, 20 wt %, 22.5 wt %, 25 wt %, 27.5 wt %, 30 wt %, 32.5 wt %, or 35 wt %, or within a range between any two of the values described herein. If the amount of the binder is within the range above, aggregation of silver nanoparticles may be further prevented and finer pattern feature may be produced. In addition, to impart sufficient conductivity to products made from the conductive ink composition, the amount of the binder based on the total weight of the binder and silver nanoparticles is preferably not higher than the range above.

The conductive ink composition comprises a solvent for the ease of handling. The solvent may be used to uniformly dissolve or disperse other components of the conductive ink composition, or to lower the viscosity of the conductive ink composition.

The type of the solvent may be selected such that it has good compatibility with the silver nanoparticles and the binder. The type of the solvent may also be selected based on the processing conditions. The solvent can be used as a single component solvent or as a mixed solvent of two or more components.

In an embodiment of the present disclosure, the solvent has a boiling point ranging from 160° C. to 270° C. For example, the boiling point of the solvent can be 160° C., 165° C., 170° C., 175° C., 180° C., 185° C., 190° C., 195° C., 200° C., 205° C., 210° C., 215° C., 220° C., 225° C., 230° C., 235° C., 240° C., 245° C., 250° C., 255° C., 260° C., 265° C., or 270° C., or within a range between any two of the values described herein. In some embodiments, if the boiling point of the solvent is outside of the range above, the conductive ink composition may be more difficult to handle or may not be sufficiently removed in the drying and sintering processes. It may affect the appearance or adhesion of the product.

In an embodiment of the present disclosure, the solvent can be alkoxy alcohol, alkoxy ester, or alicyclic alcohol. Examples of such solvent include but are not limited to ethylene glycol monobutyl ether, ethylene glycol monoisobutyl ether, ethylene glycol monohexyl ether, ethylene glycol mono-2-ethylhexyl ether, diethylene glycol monomethyl ether, diethylene glycol monoethyl ether, diethylene glycol monopropyl ether, diethylene glycol monobutyl ether (also referred to as butyl carbitol), diethylene glycol monoisobutyl ether, diethylene glycol monohexyl ether, triethylene glycol monomethyl ether, triethylene glycol monoethyl ether, triethylene glycol monopropyl ether, ethylene glycol monoethyl ether acetate, diethylene glycol monoethyl ether acetate (also referred to as carbitol acetate), diethylene glycol monobutyl ether acetate (also referred to as butyl carbitol acetate), and terpineol.

It is found that in some cases, polyol (—OH group>2) such as glycerol and ethylene glycol may be not quite compatible with some silver nanoparticle slurries or modified silver nanoparticles, and it is adverse to subsequent operations. Therefore, in an embodiment of the present disclosure, it is preferable that the solvent does not comprise polyol. In an embodiment of the present disclosure, the conductive ink composition does not comprise water.

The amount of the solvent can range from 4.9 wt % to 79.9 wt %, or 10 wt % to 75 wt %, or 25 wt % to 65 wt %, based on a total weight of the conductive ink composition. For example, based on the total weight of the conductive ink composition, the amount of the solvent can be 4.9 wt %, 5 wt %, 10 wt %, 15 wt %, 20 wt %, 25 wt %, 30 wt %, 35 wt %, 40 wt %, 45 wt %, 50 wt %, 55 wt %, 60 wt %, 65 wt %, 70 wt %, 75 wt %, or 79.9 wt %, or within a range between any two of the values described herein.

The conductive ink composition may further comprise optional components to adaptively improve the physical properties, chemical properties or processibility of the conductive ink composition. Examples of the optional components include but are not limited to additives such as adhesion promoters, coupling agents, rheology modifiers, dispersants, surfactants, fusion promoters and fluxing agents.

### Irradiation Process for Conductive Ink Composition

To form a wiring pattern, the silver nanoparticles in the conductive ink composition should be bound together. In this regard, the solvent needs to be removed after the conductive ink composition is applied to the targeted substrate, so that the silver nanoparticles can be brought into contact with one another to be further fused together. These processes are generally referred to as “drying” and “sintering” processes. In the present disclosure, the drying and sintering processes are performed in a single irradiation step with a monochromatic light, more specifically, a one-step IR laser irradiation process with particular wavelength and pulse duration.

In the present disclosure, the one-step IR laser irradiation process is performed with a wavelength ranging from 800 nm to 1150 nm, or 900 nm to 1150 nm, or 950 nm to 1100 nm. For example, the wavelength of the IR laser can be 808 nm, 830 nm, 850 nm, 905 nm, 915 nm, 920 nm, 940 nm, 950 nm, 980 nm, 1030 nm, 1053 nm, 1060 nm, 1064 nm, or 1150 nm. In an embodiment of the present disclosure, the IR laser has a wavelength of 1030 nm.

In the present disclosure, the one-step IR laser irradiation process is performed with a pulse duration of 100 femtoseconds (fs) to 1000 femtoseconds (fs), or 250 fs to 750 fs, or 400 fs to 600 fs. For example, the pulse duration can be 100 fs, 150 fs, 200 fs, 250 fs, 300 fs, 350 fs, 400 fs, 450 fs, 500 fs, 550 fs, 600 fs, 650 fs, 700 fs, 750 fs, 800 fs, 850 fs, 900 fs, 950 fs, or 1000 fs, or within a range between any two of the values described herein. When the pulse duration is within the range above, sufficient energy can be provided while heat damage can be minimized. In an embodiment of the present disclosure, the IR laser has a pulse duration of 500 fs.

In the one-step IR laser irradiation process, the solvent is removed through evaporation, allowing the silver nanoparticles to come into contact with one another and form necks that fuse them together. Meanwhile, the binder is partially photo-degraded and evaporated, leaving a portion of remaining binder that may contribute to binding the silver nanoparticles together as well as binding the silver nanoparticles to the substrate.

### Preparation of Conductive Ink Composition

The conductive ink composition of the present disclosure can be prepared by dispersing silver nanoparticles in a solution of a binder. In general, a binder may be mixed with a solvent to form a solution first, and then silver nanoparticles or a silver nanoparticle slurry may be added to the solution and mixed sufficiently to provide a conductive ink solution. The mixing processes can be performed stepwise to lower the likelihood of aggregation occurrence. Exemplary preparation methods of the conductive ink composition are provided in the Example section below.

After preparation, the conductive ink composition may have a viscosity of 2,000 to 12,000 cPs, or 3,000 to 10,000 cPs, or 5,000 to 9,000 cPs, measured at 25° C. and a shear rate of 85 s⁻¹.

### Wiring Pattern

The present disclosure also provides a wiring pattern, which is manufactured from the aforementioned conductive ink composition by a one-step IR laser irradiation process.

In general, the manufacturing processes of the wiring pattern may comprise printing the conductive ink composition on a substrate, and then performing the one-step IR laser irradiation process to form the wiring pattern. The printing method can be such as electrohydrodynamic (EHD) printing. Exemplary manufacturing processes of the wiring pattern are provided in the Example section below.

In an embodiment of the present disclosure, the wiring pattern is formed on a substrate selected from the group consisting of Cu, Ag, Ti, Ti—Al—Ti stack, glass, Al₂O₃, BaTiO₃, AlN, TiO₂, ZrO₂, polyimide (PI), polyethylene terephthalate (PET), polyethylene naphthalate (PEN), polyethylene furandicarboxylate (PEF), polycarbonate (PC), poly(methyl methacrylate) (PMMA), cyclic olefin polymer (COP), fiber-reinforced composite, and combinations thereof.

In an embodiment of the present disclosure, the wiring pattern is formed on a glass substrate. This wiring pattern has an appearance of a smooth, fine line and has good adhesion with the glass substrate.

The wiring pattern may be applied to various fields requiring different levels of conductivity. Potential applications include but are not limited to micro-circuits or interconnections in printed circuit boards, displays, advanced packaging, antennas, grounding, dissipative uses, and antistatic uses.

### EXAMPLES

Hereinafter, some examples are provided to illustrate the present disclosure. These examples are provided for illustrative purpose only and are not intended to limit the scope of the present disclosure.

### Conductive Ink Composition

The raw materials used in the Examples and Comparative Examples were listed in Table 1 below.

TABLE 1

| | Model name and | |
|---|---|---|
| Raw material | manufacturer | Description |
| Silver nanoparticle | SDU-005, | Containing 90.9 wt % of silver nanoparticles |
| slurry | available | and 9.1 wt % of butyl carbitol, wherein the |
| | from DOWA | silver nanoparticles have an average diameter |
| | | of 130 nm |
| Polyvinylpyrrolidone | Available from | Used as binder, having a weight average |
| (PVP) | Thermo-Fischer | molecular weight of 1,300,000 |
| Butyl carbitol | Available from | Used as solvent, having a boiling point of |
| | Alfa Chemistry | 230° C. |
| Ethylene glycol | Available from | Used as solvent, having a boiling point of |
| monobutyl ether | Alfa Chemistry | 171° C. |
| Triethylene glycol | Available from | Used as solvent, having a boiling point of |
| monobutyl ether | Alfa Chemistry | 280° C. |
| Ethylene glycol | Available from | Used as solvent, having a boiling point of |
| monopropyl ether | Alfa Chemistry | 150° C. |

### Preparation of Polyvinylpyrrolidone (PVP) Solution

### Preparation Example PE1

A 20 wt % PVP solution was prepared by using an overhead mechanical stirrer in a 1 L vessel jacketed with a 4 C coolant. First, 240 g of butyl carbitol were added to the vessel. 60 g of polyvinylpyrrolidone (PVP) were weighed in a tray. To prevent PVP aggregation, 10 g of PVP were added slowly every 10 min until a total 60 g of PVP were present in the solution. The solution was stirred for 4 h until PVP was fully dissolved.

### Preparation Example PE2

A 20 wt % PVP solution was prepared similarly as in Preparation Example PE1, except that butyl carbitol was replaced by ethylene glycol monobutyl ether.

### Preparation Example PE3

A 20 wt % PVP solution was prepared similarly as in Preparation Example PE1, except that butyl carbitol was replaced by triethylene glycol monobutyl ether.

### Preparation Example PE4

A 20 wt % PVP solution was prepared similarly as in Preparation Example PE1, except that butyl carbitol was replaced by ethylene glycol monopropyl ether.

### Preparation of Conductive Ink Composition

### Example E1

20 g of a silver nanoparticle slurry were weighted in a vial. A total of 4.8 g of the PVP solution of Preparation Example PE1 and 1.9 g of butyl carbitol were then stepwise added to the vial and mixed using a mixer (model number: ARE-500; available from Thinky). The steps were: adding 1 g of the PVP solution and mixing at 1000 rpm for 60 s twice, adding 2 g of the PVP solution and mixing at 1000 rpm for 60 s twice, adding 1.8 g of the PVP solution and mixing at 1000 rpm for 60 s twice, and adding 1.9 g of butyl carbitol and mixing at 1000 rpm for 60 s twice. After the adding and mixing steps were completed, the conductive ink composition of Example E1 was obtained.

### Example E2

20 g of a silver nanoparticle slurry were weighted in a vial. A total of 10.2 g of the PVP solution of Preparation Example PE1 were then stepwise added to the vial and mixed using a mixer (model number: ARE-500; available from Thinky). The steps were: adding 1 g of the PVP solution and mixing at 1000 rpm for 60 s twice, adding 2 g of the PVP solution and mixing at 1000 rpm for 60 s twice, adding 7.2 g of the PVP solution and mixing at 1000 rpm for 60 s twice. After the adding and mixing steps were completed, the conductive ink composition of Example E2 was obtained.

### Example E3

20 g of a silver nanoparticle slurry were weighted in a vial. A total of 16.1 g of the PVP solution of Preparation Example PE1 were then stepwise added to the vial and mixed using a mixer (model number: ARE-500; available from Thinky). The steps were: adding 1 g of the PVP solution and mixing at 1000 rpm for 60 s twice, adding 2 g of the PVP solution and mixing at 1000 rpm for 60 s twice, adding 13.1 g of the PVP solution and mixing at 1000 rpm for 60 s twice. After the adding and mixing steps were completed, the conductive ink composition of Example E3 was obtained.

### Example E4

20 g of a silver nanoparticle slurry were weighted in a vial. A total of 22.8 g of the PVP solution of Preparation Example PE1 were then stepwise added to the vial and mixed using a mixer (model number: ARE-500; available from Thinky). The steps were: adding 1 g of the PVP solution and mixing at 1000 rpm for 60 s twice, adding 2 g of the PVP solution and mixing at 1000 rpm for 60 s twice, adding 19.8 g of the PVP solution and mixing at 1000 rpm for 60 s twice. After the adding and mixing steps were completed, the conductive ink composition of Example E4 was obtained.

### Example E5

20 g of a silver nanoparticle slurry were weighted in a vial. A total of 49 g of the PVP solution of Preparation Example PE1 were then stepwise added to the vial and mixed using a mixer (model number: ARE-500; available from Thinky). The steps were: adding 1 g of the PVP solution and mixing at 1000 rpm for 60 s twice, adding 2 g of the PVP solution and mixing at 1000 rpm for 60 s twice, adding 46 g of the PVP solution and mixing at 1000 rpm for 60 s twice. After the adding and mixing steps were completed, the conductive ink composition of Example E5 was obtained.

### Example E6

The conductive ink composition of Example E6 was prepared similarly as in Example E2, except that the PVP solution of Preparation Example PE1 was replaced by the PVP solution of Preparation Example PE2.

### Comparative Example CE1

20 g of a silver nanoparticle slurry were weighted in a vial. Then, 0.42 g of butyl carbitol were added to the vial and mixed using a mixer (model number: ARE-500; available from Thinky) at 1000 rpm for 60 s twice, and the conductive ink composition of Comparative Example CE1 was obtained. Note that in Comparative Example CE1, no PVP was added.

### Comparative Example CE2

20 g of a silver nanoparticle slurry were weighted in a vial. A total of 2.9 g of the PVP solution of Preparation Example PE1 and 7.4 g of butyl carbitol were then stepwise added to the vial and mixed using a mixer (model number: ARE-500; available from Thinky). The steps were: adding 1 g of the PVP solution and mixing at 1000 rpm for 60 s twice, adding 1.9 g of the PVP solution and mixing at 1000 rpm for 60 s twice, and adding 7.4 g of butyl carbitol and mixing at 1000 rpm for 60 s twice. After the adding and mixing steps were completed, the conductive ink composition of Comparative Example CE2 was obtained.

### Comparative Example CE3

The conductive ink composition of Comparative Example CE3 was prepared similarly as in Example E2, except that the PVP solution of Preparation Example PE1 was replaced by the PVP solution of Preparation Example PE3.

### Comparative Example CE4

The conductive ink composition of Comparative Example CE4 was prepared similarly as in Example E2, except that the PVP solution of Preparation Example PE1 was replaced by the PVP solution of Preparation Example PE4.

### Wiring Pattern

### Electrohydrodynamic (EHD) Printing

The conductive ink compositions of Examples E1-E6 and Comparative Examples CE1-CE4 were used for electrohydrodynamic (EHD) printing. The EHD printing was performed using an EHD printer (model number: MX2, available from ENJET) to print the conductive ink composition on a glass substrate to form parallel lines on the substrate. The nozzle used has an inner diameter of 25 μm and an outer diameter of 55 μm and was set at a distance of 100 μm apart from the substrate. The conductive ink composition was loaded and then pumped through the nozzle and driven by a voltage of 1 kV and a pressure of 20 kPa, while the substrate was moved at a speed of 100 mm/s, thereby forming a printed pattern on the substrate.

The printed patterns of Examples E1-E6 and Comparative Examples CE1-CE4 were observed under an optical microscope installed on the EHD printer. It is found that Comparative Examples CE1-CE2 did not form parallel lines by EHD printing.

### Pressure-Controlled Direct Printing

Since Comparative Examples CE1-CE2 cannot form parallel lines by EHD printing, they were processed by pressure-controlled direct printing to produce printed patterns. The pressure-controlled direct printing was performed using a dispenser (model number: S-SIGMA-CM3-V5, available from Musashi). The nozzle used has an inner diameter of 60 μm and an outer diameter of 100 μm and was set at a distance of 80 μm apart from the substrate. The conductive ink composition was loaded and then extruded through the nozzle by a pressure of 10 kPa, while the substrate was moved at a speed of 5 mm/s, thereby forming a printed pattern on the substrate.

### IR Laser Irradiation

The printed patterns of the Examples and Comparative Examples were irradiated with a 1030-nm IR laser (an IR femtosecond laser integrated by CohPros) for sintering to form wiring patterns. The sintering process was performed in one step with a pulse duration of 500 femtosecond and a repetition rate of 100 kHz. The laser sintering parameters were optimized by setting the output power within 1 W to 5 W, the Z offset within 1 mm to 5 mm, the hatch pitch within 5 μm to 50 μm, and the scan velocity within 50 mm/s to 2000 mm/s.

### Test Methods

### [Viscosity]

The viscosity of the conductive ink composition is measured by a rheometer (Waters, Discovery Hybrid Rheometer-2, available from TA Instruments) at 25° C. and a shear rate of 85 s⁻¹. The unit for viscosity is cP.

### [Adhesion]

A wiring pattern of 10 parallel lines on a glass substrate is used as the specimen, and a cross-hatch tape test modified from ASTM D3359 is performed to evaluate the adhesion of the wiring pattern to the substrate.

Initially, a first cut is made through the 10 parallel lines at 90° to the lines. Subsequently, a second cut parallel to and spaced 10 mm apart from the first cut is made through the 10 parallel lines to cut them into 10 line segments. Then, a third cut parallel to and spaced 10 mm apart from the second cut is made to produce another 10 line segments. The cutting process is repeated until a grid of 10×10 line segments is made. The grid is then softly brushed to remove debris produced from the cuts.

A tape (3M 610 Tape, available from 3M) is placed over the grid and pressed smoothly to ensure uniform contact with the line segments, which may be confirmed from uniform color tone of the contact area. Within 90 seconds from tape application, the tape is then removed by pulling it back at 180° along the direction of the line segments (perpendicular to the direction of cuts).

Afterward, the specimen is inspected under optical microscope (LSM 900, available from Zeiss). The adhesion is evaluated according to the following criteria:
5B: all line segments remain intact and no detachment happens,
4B: less than 5% of the line segments are suffered from detachment,
3B: 5% to less than 15% of the line segments are suffered from detachment,
2B: 15% to less than 35% of the line segments are suffered from detachment,
1B: 35% to less than 65% of the line segments are suffered from detachment, and
0B: 65% or more of the line segments are suffered from detachment

### Examples E1-E5 and Comparative Examples CE1-CE2

The conductive ink compositions and wiring patterns of Examples E1-E5 and Comparative Examples CE1-CE2 were tested for viscosity and adhesion according to the method described in previous sections. Additionally, the sintered appearance of the wiring patterns is also inspected. The results are summarized in Table 2.

TABLE 2

| | Binder amount based | | | |
|---|---|---|---|---|
| | on binder and silver | Viscosity | | |
| | nanoparticles (wt %) | (cp) | Adhesion | Sintered appearance |
| E1 | 5 | 5615 | 5B | Fine lines |
| E2 | 10 | 6213 | 5B | Fine lines |
| E3 | 15 | 8536 | 5B | Fine lines |
| E4 | 20 | 7045 | 5B | Fine lines |
| E5 | 35 | 5514 | 5B | Fine lines |
| CE1 | 0 | 6413 | 0B | t1: no continuous structure |
| | | | | t2: loose lines that peel easily |
| CE2 | 3 | 5104 | 3B | t1: wavy strings intersecting |
| | | | | with one another |
| | | | | t2: loose lines that peel easily |

*t1 represents results from EHD printing.
*t2 represents results from pressure-controlled direct printing.

As shown in Table 2, the conductive ink compositions of Examples E1-E5 have been successfully formed into wiring patterns by the one-step IR laser irradiation process. The wiring patterns of Examples E1-E5 have good sintered appearance and excellent adhesion to substate. On the other hand, the conductive ink compositions of Comparative Examples CE1-CE2 have difficulties to be formed into lines by EHD printing. Even with pressure-controlled direct printing and the same one-step IR laser irradiation process, Comparative Examples CE1-CE2 only produce loose lines and have poor adhesion with the substrate.

Additionally, some wiring patterns are tested for bulk resistivity by a standard four-probe method. Moderate result is obtained for Example E3 at 300 μΩ·cm, and excellent results are obtained for Examples E1 and E2 at 10 μΩ·cm and 14 μΩ·cm, respectively.

### Examples E2, E6 and Comparative Examples CE3-CE4

The conductive ink compositions and wiring patterns of Examples E2, E6 and Comparative Examples CE3-CE4 were tested for viscosity and adhesion according to the method described in previous sections. Additionally, the sintered appearance of the wiring patterns is also inspected. The results are summarized in Table 3.

TABLE 3

| | | Viscosity | | Sintered |
|---|---|---|---|---|
| | Solvent | (cp) | Adhesion | appearance |
| E2 | Butyl carbitol | 6213 | 5B | Fine lines |
| E6 | Ethylene glycol monobutyl ether | 5825 | 5B | Fine lines |
| CE3 | Triethylene glycol monobutyl ether | 6417 | 0B | Bulging, bumping |
| CE4 | Ethylene glycol monopropyl ether | 5791 | 0B | Brittle |

As shown in Table 3, although all conductive ink compositions can be processed by EHD printing and sintered by the one-step IR laser irradiation process, different solvents may result in different performance in adhesion and sintered appearance. Such different performance may be due to the boiling point of the solvent.

While some embodiments are provided in the specification, they are only illustrative of the present disclosure and are not intended to limit the protection scope of the present disclosure. Persons skilled in the art may proceed with a variety of modifications based on the disclosure as described without departing from the principle thereof. The protection scope of the present disclosure is as defined in the following claims.

What is claimed is:

1. A conductive ink composition for forming a wiring pattern by a one-step IR laser irradiation process,
wherein based on a total weight of the conductive ink composition, the conductive ink composition comprises:
(A) 20 wt % to 95 wt % of silver nanoparticles;
(B) 0.1 wt % to 20 wt % of a binder; and
(C) 4.9 wt % to 79.9 wt % of a solvent;
wherein based on a total weight of the binder (B) and silver nanoparticles (A), the amount of the binder (B) is 4 wt % to 45 wt %; and
wherein the one-step IR laser irradiation process is performed with a wavelength ranging from 800 nm to 1150 nm and a pulse duration of 100 femtoseconds to 1000 femtoseconds.

2. The conductive ink composition of claim 1, wherein the conductive ink composition has a viscosity of 2,000 to 12,000 cPs measured at 25° C. and a shear rate of 85 s⁻¹.

3. The conductive ink composition of claim 1, wherein the silver nanoparticles (A) have an average diameter of 20 nm to 400 nm.

4. The conductive ink composition of claim 1, wherein the binder (B) is selected from the group consisting of poly(vinyl acetate), poly(vinyl alcohol) (PVA), polydioxanone (PDO), polyacrylamide (PAM), poly(glycolic acid) (PGA), poly-(ε-caprolactone) (PCL), poly(L-lactic acid) (PLLA), polyurethane (PU), polyacrylate, polyvinylpyrrolidone (PVP), poly(vinyl alcohol-co-ethylene), polyethylene glycol (PEG), poly(tetramethylene ether) glycol (PTMEG), ethyl cellulose (EC), cellulose acetate, hydroxypropylmethyl cellulose (HPMC), polyvinyl butyral (PVB), and combinations thereof.

5. The conductive ink composition of claim 1, wherein the solvent (C) has a boiling point ranging from 160° C. to 270° C.

6. The conductive ink composition of claim 1, wherein the solvent (C) is alkoxy alcohol, alkoxy ester, or alicyclic alcohol.

7. The conductive ink composition of claim 6, wherein the solvent (C) is selected from the group consisting of ethylene glycol monobutyl ether, ethylene glycol monoisobutyl ether, ethylene glycol monohexyl ether, ethylene glycol mono-2-ethylhexyl ether, diethylene glycol monomethyl ether, diethylene glycol monoethyl ether, diethylene glycol monopropyl ether, diethylene glycol monobutyl ether, diethylene glycol monoisobutyl ether, diethylene glycol monohexyl ether, triethylene glycol monomethyl ether, triethylene glycol monoethyl ether, triethylene glycol monopropyl ether, ethylene glycol monoethyl ether acetate, diethylene glycol monoethyl ether acetate, diethylene glycol monobutyl ether acetate, and terpineol.

8. The conductive ink composition of claim 1, wherein the solvent (C) is void of polyol or water.

9. A wiring pattern, which is manufactured from the conductive ink composition of claim 1 by the one-step IR laser irradiation process.

10. The wiring pattern of claim 9, which is formed on a substrate selected from the group consisting of Cu, Ag, Ti, Ti—Al—Ti stack, glass, Al₂O₃, BaTiO₃, AlN, TiO₂, ZrO₂, polyimide (PI), polyethylene terephthalate (PET), polyethylene naphthalate (PEN), polyethylene furandicarboxylate (PEF), polycarbonate (PC), poly(methyl methacrylate) (PMMA), cyclic olefin polymer (COP), fiber-reinforced composite, and combinations thereof.
